(19) United States
(12) Patent Application Publication
(10) Pub. No.: US 2018/0059179 A1
(43) Pub. Date: Mar. 1, 2018

(54) AUTOMATIC CONTROL SYSTEM AND AUTOMATIC INSTRUMENT SEARCHING METHOD FOR THE SAME

(71) Applicant: Primax Electronics Ltd., Taipei (TW)

(72) Inventors: PEI-MING CHANG, Taipei (TW); SHIH-CHIEH HSU, Taipei (TW); SHI-JIE ZHANG, Taipei (TW); WEI-LUNG HUANG, Taipei (TW)

(21) Appl. No.: 15/366,480

(22) Filed: Dec. 1, 2016

(30) Foreign Application Priority Data
Aug. 26, 2016 (TW) 105127465

(51) Int. Cl. G01R 31/3187; G06F 13/42

(52) U.S. Cl. CPC G01R 31/3187; G06F 13/4282

(57) ABSTRACT

An automatic instrument searching method and an automatic control system are provided. The automatic control system includes a computer, plural serial ports and at least one measuring instrument. The at least one measuring instrument is connected with computer through the plural serial ports. Firstly, the computer detects a number of the plural serial ports and arranges the serial ports. Then, the plural serial ports are inquired according to plural different communication protocols. Then, the at least one measuring instrument makes a response to a setting of the matched communication protocol. If one of the inquired serial ports receives the response, the computer judges that the serial port is connected with one measuring instrument and issues a verification command to the connected measuring instrument. If the measuring instrument complies with the verification command, the measuring instrument is addressed.

### FIELD OF THE INVENTION

The present invention relates to an automatic control system and an automatic instrument searching method, and more particularly to a system and a method of using a control program to automatically recognize the connection statuses of serial ports and measuring instruments of the system in order to shorten the setting time.

### BACKGROUND OF THE INVENTION

In the modern electronic factories, electronic products have to be tested before the electronic products leave the factories. For example, in addition to a functional circuit test (FCT) prior to shipment, a printed circuit board (PCB) has to undergo an in circuit test (ICT). In fact, the in circuit test is a circuitry test or an electrical property test. Generally, an electronic measuring instrument, also referred as a multimeter, is employed to measure under-test objects of the printed circuit board. That is, a probe of the electronic measuring instrument is directly used to perform a voltage test, a current test, an open-circuit test or a short-circuit test on a resistor, a power source, a switch element or other components.

By automatically or manually monitoring the testing results, the testing results can be realized. Generally, in a production line of a factory, plural measuring instruments perform the in circuit tests simultaneously. For achieving the labor-saving and time-saving purposes, the measuring instruments are connected to a computer or a monitor through transmission wires. Consequently, the testing result of these measuring instruments can be operated and checked by the supervisor.

FIG. 1 is a schematic functional block diagram illustrating the architecture of a conventional in circuit test system. As shown in FIG. 1, the conventional in circuit test system comprises four measuring instruments 11, 12, 13 and 14 and a computer 10. The types or models of these measuring instruments 11, 12, 13 and 14 may be identical. That is, the measuring functions of these measuring instruments may be identical. Each of the measuring instruments 11, 12, 13 and 14 has a display screen and associated keys for allowing the engineer to view and operate. Moreover, when a system program is executed in the computer, a user interface 100 is shown on a monitor of the computer 10. Through the data and the operation items shown on the user interface 100, the supervisor can monitor and control these measuring instruments 11, 12, 13 and 14.

The measuring instruments 11, 12, 13 and 14 are in communication with the computer 10 to transmit signals through a general purpose interface bus (GPIB), an Ethernet interface, a serial port or any other appropriate transmission interface. For example, the serial port includes a RS232 port, a RS422 port or a RS485 port. As known, the serial port (or Com port) and the measuring instrument are connected with each other in a one-to-one relationship. That is, one serial port is allowed to be connected with one measuring instrument. Moreover, one computer is equipped with or expansively connected with plural serial ports. The number of the plural serial ports of the computer is more than or equal to the total number of the serial ports of the measuring instruments.

Conventionally, the serial ports to be connected with the corresponding measuring instruments should be previously set before the in circuit test is performed. Consequently, the computer 10 at the back end can effectively identify the serial ports. In case that the production instruments in the production line are increased and the production line is expanded, the number of the measuring instruments is also increased. When the number of the measuring instruments is increased or some of the measuring instruments are damaged and replaced with new ones, the system program needs to be correspondingly adjusted and set.

According to the existing technology, the connection between the transmission wire and the serial port of the measuring instrument is manually set. That is, after the system program is executed to sequentially correct and check all of the serial ports, the connections between all measuring instruments and the corresponding serial ports can be realized. A process of setting the connection between the transmission wire and the serial port of the measuring instrument will be described in more detail as follows. Firstly, an initiation file (e.g., Setup.ini) for setting is established through a text file. Then, the number of the serial ports (e.g., RS232) is declared again and the program is compiled. After the initiation file is read, the corresponding serial ports are set according to the initial values of the initiation file. Meanwhile, the setting process is completed.

The conventional setting process is time-consuming and labor-intensive because the supervisor cannot clearly recognize which serial ports are connected with the corresponding measuring instruments. Once the setting is erroneous, some problems occur. For example, the measuring instrument 11 as shown in FIG. 1 complies with an 8-bit data transmission format according to the setting. If the serial port corresponding to the measuring instrument 11 complies with a 7-bit format, the system program is disabled, the computer crashes with no response, or an erroneous message that is unable to process is generated. In this situation, the supervisor has to debug the system program or perform the setting process again.

In case that the extent of expanding the production line is increased, it takes much time to adjust and set the system program. Since the production line is possibly stopped, the procedures of the overall factory are adversely affected. Therefore, it is important to develop a control system or a strategy to deal with the update condition of the instruments in the production line.

### SUMMARY OF THE INVENTION

The present invention provides an automatic control system and an automatic instrument searching method for the automatic control system. By the system and method of the present invention, the initiation file for setting is not established, and it is not necessary to manually and sequentially correct and check all of the serial ports through the program. Since a control program is directly used to automatically judge and search the connection states of the serial ports and the measuring instruments, the time period of setting the measuring instruments is largely reduced.

In accordance with an aspect of the present invention, there is provided an automatic instrument searching method for an automatic control system. The automatic control system includes a computer, plural serial ports and at least one measuring instrument. The at least one measuring instrument is connected with the computer through the plural serial ports. Firstly, the computer detects a number of the plural serial ports and arranges the plural serial ports. Then, the plural serial ports are inquired according to plural different communication protocols. Then, the at least one measuring instrument makes a response to a setting of the matched communication protocol. If one of the inquired serial ports receives the response, the computer judges that the serial port is connected with one of the at least one measuring instrument and issues a verification command to the connected measuring instrument to perform a verifying process. If the measuring instrument in the verifying process complies with the verification command, the measuring instrument is addressed.

In accordance with another aspect of the present invention, there is provided an automatic control system with an automatic instrument searching function. The automatic control system includes at least one measuring instrument, a computer and plural serial ports. A control program is installed in the computer. The plural serial ports are connected with the at least one measuring instrument. When the control program is executed, the computer detects a number of the plural serial ports and arranges the plural serial ports, the plural serial ports are inquired according to plural different communication protocols, and the at least one measuring instrument makes a response to a setting of the matched communication protocol. If one of the inquired serial ports receives the response, the computer judges that the serial port is connected with one of the at least one measuring instrument and issues a verification command to the connected measuring instrument to perform a verifying process. If the measuring instrument in the verifying process complies with the verification command, the computer addresses the measuring instrument.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic functional block diagram illustrating the architecture of a conventional in circuit test system;

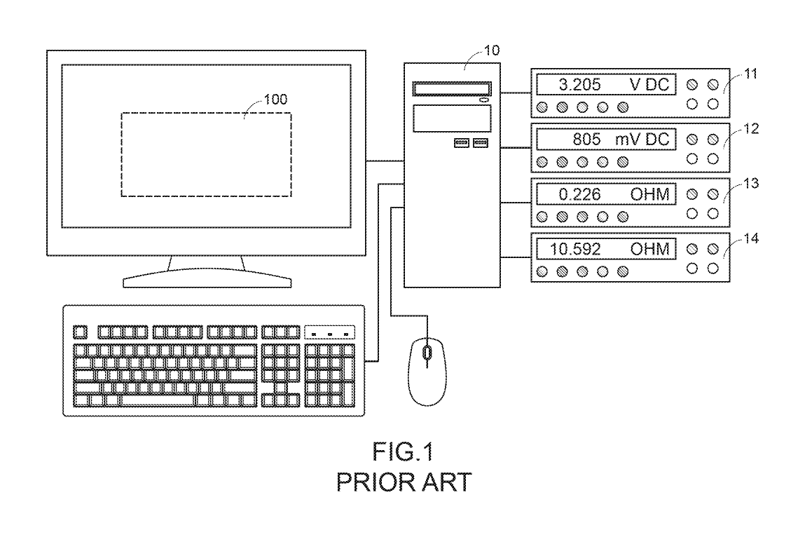

FIG. 2 is a schematic functional block diagram illustrating an automatic control system according to an embodiment of the present invention; and

FIG. 3 is a flowchart illustrating an automatic instrument searching method according to an embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. In the following embodiments and drawings, the elements irrelevant to the concepts of the present invention are omitted and not shown.

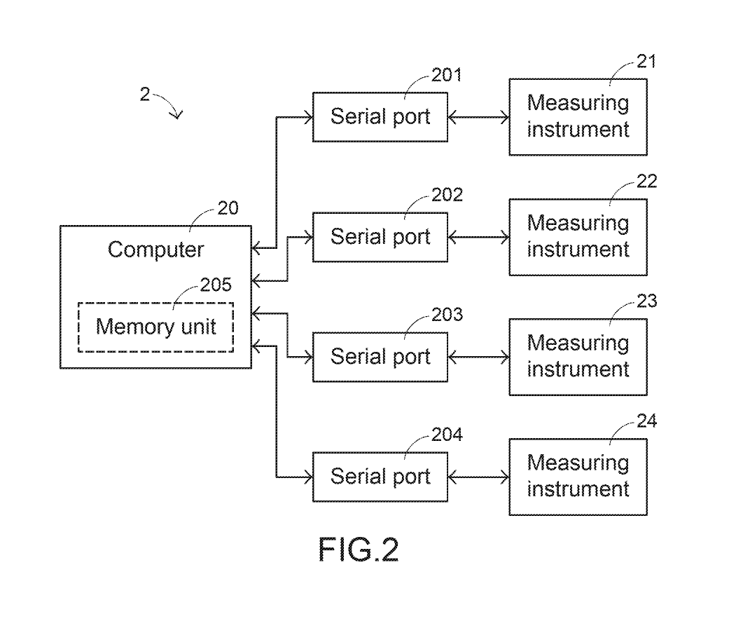

The present invention provides an automatic control system and an automatic instrument searching method for the automatic control system. FIG. 2 is a schematic functional block diagram illustrating an automatic control system according to an embodiment of the present invention. As shown in FIG. 2, the automatic control system 2 comprises a computer 20, plural serial ports and plural measuring instruments. In this embodiment, four serial ports 201, 202, 203 and 204 and four measuring instruments 21, 22, 23 and 24 are shown. Moreover, the serial ports and the corresponding measuring instruments are connected with each other in a one-to-one relationship. That is, each measuring instrument is connected with one of the four serial ports 201˜204. One serial port is connected with one measuring instrument only.

The automatic control system 2 in this embodiment comprises the four measuring instruments 21, 22, 23 and 24. It is noted that the number of the measuring instruments is not restricted. That is, the computer of the automatic control system of the present invention can be applied to at least one measuring instrument. In case that the automatic control system comprises plural serial ports, the single measuring instrument can be connected with any selected serial port. For measuring the electrical properties of the measuring instrument, it is necessary to recognize which serial port is connected with the measuring instrument. Generally, the automatic control system is used for testing plural measuring instruments. For effectively monitoring the measuring instruments at the back end, the number of the serial ports is equal to or more than the number of the measuring instruments.

Moreover, the serial ports 201˜204 provide expanded connection capability to the computer 20. That is, the original serial ports of the computer 20 having the same specification as the serial ports 201˜204 is less than four. In an embodiment, a one-to-many adapting unit (not shown) is employed to expand the number of the serial ports. In another embodiment, plural serial ports are directly installed on the computer. That is, the computer is equipped with plural serial ports to be connected with the same number of measuring instruments.

The automatic instrument searching method of the present invention is applied to the measuring instruments and the serial ports with RS232 (Recommend Standard number 232) transmission interface. According to the existing technology, the RS232 transmission interface can be used to control the systematic testing process of the general measuring instrument. For effectively transmitting signals, it is preferred that the measuring instruments 21, 22, 23 and 24 are connected with the corresponding serial ports 201, 202, 203 and 204 through transmission wires. Moreover, the connectors of the serial ports 201, 202, 203 and 204 are 9-pin connectors (i.e., DB9). According to the existing technology, the transmission wires complying with the RS232 specification is about 50˜100 feet.

Like the conventional technology, a system program is previously installed in the computer 20 of the automatic control system 2. For example, the system program is stored in a memory unit 205 of the computer. When the system program is executed, the supervisor can monitor and operate the operations of the automatic control system 2 through a user interface shown on a display screen. For example, the supervisor can monitor the data input/output condition of each serial port. In accordance with the automatic instrument searching method of the present invention, a control program of the system program is executed to automatically search the connected instruments. In more detail, the control program is developed or written by the supervisor or the software engineer through the system program.

As mentioned above, the automatic instrument searching method is started when the control program is executed in the computer 20. Before the control program is executed, it is necessary to connect the measuring instruments 21˜24 with the corresponding serial ports 201˜204 and turn on the measuring instruments 21˜24.

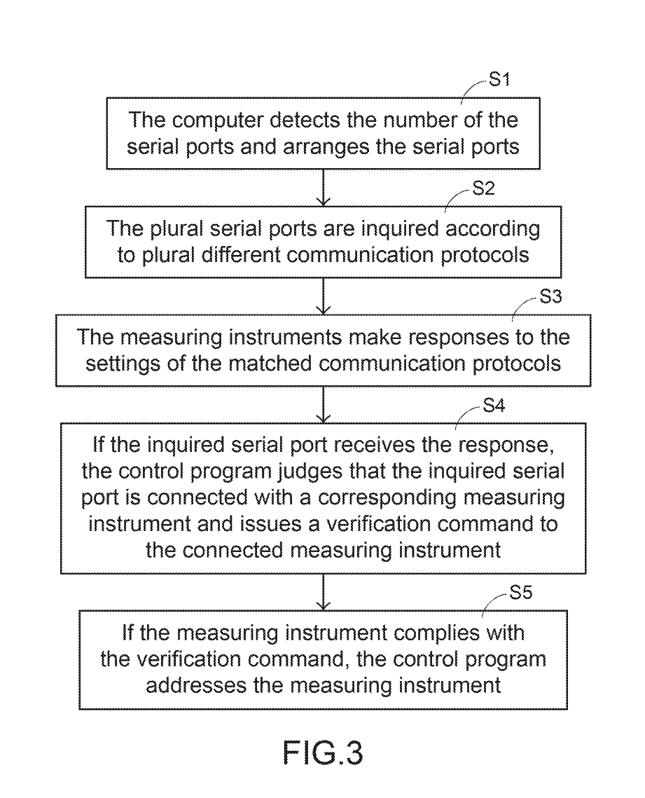

FIG. 3 is a flowchart illustrating an automatic instrument searching method according to an embodiment of the present invention. Firstly, the computer 20 detects the number of the serial ports 201˜204 and arranges the serial ports 201˜204 (Step S1). Then, the computer 20 inquires the plural serial ports 201˜204 according to plural different communication protocols (Step S2). Then, the measuring instruments 21˜24 make responses to the settings of the matched communication protocols (Step S3). If the inquired serial port receives the response, the control program judges that the inquired serial port is connected with a corresponding measuring instrument and issues a verification command to the connected measuring instrument (Step S4). If the measuring instrument complies with the verification command, the control program addresses the measuring instrument (Step S5).

In the step S1, the serial ports 201˜204 are used as the expanded transmission interface of the computer. When the serial ports 201˜204 are detected by the computer 20, the computer 20 can judge the number of the serial ports 201˜204. In this embodiment, the number of RS232 transmission interface is firstly detected. After all of the serial ports are detected, the way of arranging the serial ports is not restricted. In an embodiment, the serial ports are arranged according to the sequence of connecting to the computer 20. For example, the serial port 201 is defined as a first serial port, the serial port 202 is defined as a second serial port, and the rest may be deduced by analogy. Consequently, the addresses and names of the serial ports can be recognized.

After the step S1 is completed, all of the serial ports connected with the computer 20 are detected. In some practical situations (e.g., not the situation of FIG. 2), some of the serial ports are not connected with the measuring instruments. Then, plural different communication protocols are provided to each serial port to judge whether the serial port is connected with any measuring instrument. The communication protocol indicates a communication standard for transferred data between a transmitter terminal and a receiver terminal. For achieving the effective communication, both of the transmitter terminal and the receiver terminal need to have the same contents of the communication protocol. For example, the contents of the communication protocol contain a Baud rate setting, a data bit setting, a stop bit setting and a parity bit setting.

When the measuring instruments 21˜24 are connected with the serial ports 201˜204, the measuring instruments 21˜24 have their communication protocols, or the communication protocols can be further set through instrument panels (e.g., display screens and keys) of the measuring instruments 21˜24. For example, the Baud rate is set as 9600, 4800, 2400 or 1200 bits per second, the data bits have the length of 8 bits or 7 bits, the stop bit is 1 or “None”, and the parity bit is “None”, “Odd” or “Even” (i.e., a parity check). That is, the possible settings of the communication protocols of the measuring instruments 21˜24 are the combinations of the above contents.

In the steps S2 and S3, the plural different communication protocols are the possible combinations of the above setting contents that are previously managed by the control program. That is, the plural different communication protocols are set and compiled according to the applications of the measuring instruments 21˜24. Then, the computer 20 inquires the plural serial ports 201˜204 according to the plural different communication protocols sequentially. If the setting of the communication protocol of the inquired measuring instrument matches the communication protocol of the inquired serial port, it means that the communication protocols of the transmitter terminal and the receiver terminal are identical. Consequently, the inquired measuring instrument and the inquired serial port can communicate with each other. Meanwhile, the inquired measuring instrument makes a response in order to notify the control program that the data transmission can be performed.

If the inquired serial port does not receive the response in the step S4, the control program judges that the inquired serial port is not connected with any measuring instrument. Whereas, if the inquired serial port receives the response in the step S4, the control program judges that the inquired serial port is connected with the corresponding measuring instrument. The process of judging whether the inquired serial port is connected with the corresponding measuring instrument comprises the following steps. Firstly, the computer 20 inquires a specified serial port of the plural serial ports 201˜204 according to one of the plural different communication protocols. If no response is received after a predetermined time period, the computer inquires the specified serial port according to another of the plural different communication protocols. If no response is received after the specified serial port is inquired according to the plural different communication protocols, the computer judges that the specified serial port is connected with none of the at least one measuring instrument and inquires another serial port of the plural serial ports according to the plural different communication protocols.

For example, if the first serial port (e.g., the serial port 201) is inquired according to a first communication protocol and no response is received, it means that the first serial port is not connected with any measuring instrument or the communication protocol of the measuring instrument connected with the first serial port does not match the first communication protocol. Then, the first serial port is inquired according to a second communication protocol. Since the plural managed communication protocols contain the possible settings of the plural measuring instruments, the way of sequentially inquiring the first serial port according to the different communication protocols can realize whether the first serial port is connected with any measuring instrument.

Since the serial port is inquired according to another communication protocol if no response is received after a predetermined time period, the control program will not continuously wait for receiving the response. Consequently, the problem of causing crash or suspension of the computer will be avoided. After the time period of waiting for the response reaches the predetermined time period (Time out), the current state is escaped, and the searching process is continuously according to another condition or the judging result is directly determined.

That is, after the process of judging whether a specified serial port (e.g., the serial port 201) is connected with any measuring instrument, the same process is performed to inquire the other serial ports (e.g., the serial ports 202˜204) and wait for the response. Consequently, the connection states of all serial ports can be realized. It is noted that the way of judging whether a specified serial port is connected with any measuring instrument may be modified. For example, if the inquired serial port receives a response according to one of the plural communication protocols, the process of inquiring the same serial port according to the other communication protocols is not done. Consequently, the searching time is reduced.

In case that no response is received after the specified serial port is inquired according to all of the plural different communication protocols, the reason may be that the specified serial port is connected with the measuring instrument but the communication protocol of the measuring instrument cannot be recognized. Under this circumstance, it is considered that the measuring instrument is not connected with the serial port. Since the connection state of the measuring instrument is not realized, the communication between the computer and the measuring instrument is not established.

After the control program judges that a specified serial port is connected with the corresponding measuring instrument in the steps S4 and S5, the control program issues a verification command to the connected measuring instrument. Generally, even if the control program judges that the specified serial port is connected with the corresponding measuring instrument, the control program cannot realize whether the measuring instrument is able to perform the electrical property testing task of the present automatic control system. The process of issuing the verification command to the connected measuring instrument can further judge whether the measuring instrument is able to perform the electrical property testing task.

Especially, the contents of the verification command contain a predetermined brand data or a predetermined machine model data. That is, the process of issuing the verification command to the connected measuring instrument is used to compare the brand name or the model number of the connected measuring instrument with the predetermined brand data or the predetermined machine model data. For example, the predetermined brand data is “HEWLETT-PACKARD”, and the predetermined machine model data is “34401A”. In an embodiment, the control program is designed to have a function of judging whether the message of the response from the connected measuring instrument contains the string “HEWLETT-PACKARD” or “34401A”. If the brand name or the model number of the connected measuring instrument is identical to the predetermined brand data or the predetermined machine model data, the control program judges that the connected measuring instrument complies with the verification command.

In the above embodiment, the contents of the verification command contain a predetermined brand data or a predetermined machine model data. That is, the measuring instruments 21˜24 are designated to have the same machine model or the same brand in order to be searched and perform the subsequent transmission process. It is noted that numerous modifications and alterations may be made while retaining the teachings of the invention. For example, in another embodiment, the strings to be judged contain at least two predetermined brand data or at least two predetermined machine model data. Under this circumstance, the measuring instruments can be substituted or the connecting flexible is enhanced.

In the step S5, the measuring instrument complying with the verification command is addressed. That is, after the measuring instruments connected with the corresponding serial ports are automatically searched, the step S5 is used to realize the allocation of the measuring instruments in the automatic control system. For example, as shown in FIG. 2, the measuring instrument 21 is connected with the serial port 201 according to the allocation.

After the measuring instrument connected with a specified serial port is automatically searched and addressed, the control program searches the measuring instruments that are connected with the other serial ports by using the similar process. That is, except for the serial port 201 connected with the addressed measuring instrument 21, the other serial ports 202˜204 are inquired according to the plural different communication protocols. The way of making the responses from the other measuring instruments and the way of judging the connection states are similar.

In accordance with another feature of the present invention, the searched serial ports or the searched measuring instruments will not be searched again. Consequently, while the connection states of all serial ports and all measuring instruments are confirmed, the measuring instruments are addressed. As shown in FIG. 2, the measuring instrument 22 is connected with the serial port 202, the measuring instrument 23 is connected with the serial port 203, and the measuring instrument 24 is connected with the serial port 204.

Regardless of whether the serial ports are connected with the corresponding measuring instruments or which serial ports are connected with the corresponding measuring instruments, the automatic instrument searching method and the automatic control system can automatically search the measuring instruments.

Moreover, the above steps and the corresponding results can be stored in the memory unit 205. That is, the addressing results of the measuring instruments can be saved as an initiation file and stored in the memory unit 205. Consequently, the initiation file can be read in the next operation. If the connection states of the measuring instruments are not changed when the automatic control system is operated in the next time, the control system will directly read and use the initiation file without the need of searching the measuring instruments again. When the production line is expanded or the connection states of the measuring instruments are changed, it is not necessary to perform the previous flowchart again.

From the above descriptions, the present invention provides an automatic control system and an automatic instrument searching method. The technologies of the present invention have many benefits. Firstly, the initiation file (e.g., Setup.ini) for setting is not established in the startup stage, and it is not necessary to manually and sequentially correct and check all of the serial ports through the program. That is, the control program is directly used to automatically judge and search the connection states of the serial ports and the measuring instruments. Secondly, in comparison with the conventional technology of sequentially setting the serial ports, the technology of the present invention is more user-friendly because the possible communication protocols are taken into consideration. Thirdly, when the production line is expanded or the system is updated, the automatic instrument searching method of the present invention can largely reduce the time period of setting the measuring instruments. Consequently, the production line is not stopped.

The automatic control system and the automatic instrument searching method of the present invention can solve the drawbacks of the conventional technologies while achieving the purposes of the present invention.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. An automatic instrument searching method for an automatic control system, the automatic control system comprising a computer, plural serial ports and at least one measuring instrument, the at least one measuring instrument being connected with the computer through the plural serial ports, the automatic instrument searching method comprising steps of:
the computer detecting a number of the plural serial ports and arranging the plural serial ports;
inquiring the plural serial ports according to plural different communication protocols;
the at least one measuring instrument making a response to a setting of the matched communication protocol;
if one of the inquired serial ports receives the response, judging that the serial port is connected with one of the at least one measuring instrument and issuing a verification command to the connected measuring instrument to perform a verifying process; and
if the measuring instrument in the verifying process complies with the verification command, addressing the measuring instrument.

2. The automatic instrument searching method according to claim 1, further comprising steps of:
inquiring a specified serial port of the plural serial ports according to one of the plural different communication protocols;
if no response is received after a predetermined time period, inquiring the specified serial port according to another of the plural different communication protocols; and
if no response is received after the specified serial port is inquired according to all of the plural different communication protocols, judging that the specified serial port is connected with none of the at least one measuring instrument and inquiring another serial port of the plural serial ports according to the plural different communication protocols.

3. The automatic instrument searching method according to claim 1, wherein after the measuring instrument connected with a specified serial port is addressed, the automatic instrument searching method further comprises a step of inquiring other serial ports according to the plural communication protocols.

4. The automatic instrument searching method according to claim 1, wherein the computer comprises a memory unit, and addressing results of the corresponding measuring instruments are saved as an initiation file and stored in the memory unit, wherein the initiation file is read by the computer when the automatic control system is operated in a next time.

5. The automatic instrument searching method according to claim 1, wherein the number of the plural serial ports is equal to or more than a number of the at least one measuring instrument, wherein each measuring instrument is connected with a corresponding serial port of the plural serial ports.

6. The automatic instrument searching method according to claim 1, wherein each of the plural communication protocols contains a Baud rate setting, a data bit setting, a stop bit setting and a parity bit setting.

7. The automatic instrument searching method according to claim 1, wherein the plural communication protocols are set and compiled according to applications of the at least one measuring instrument.

8. The automatic instrument searching method according to claim 1, wherein the verification command contains a predetermined brand data or a predetermined machine model data, wherein if a brand name or a model number of the connected measuring instrument is identical to the predetermined brand data or the predetermined machine model data, the computer judges that the connected measuring instrument complies with the verification command.

9. An automatic control system with an automatic instrument searching function, the automatic control system comprising:
at least one measuring instrument;
a computer, wherein a control program is installed in the computer; and
plural serial ports connected with the at least one measuring instrument,
wherein when the control program is executed, the computer detects a number of the plural serial ports and arranges the plural serial ports, the computer inquires the plural serial ports according to plural different communication protocols, and the at least one measuring instrument makes a response to a setting of the matched communication protocol, wherein if one of the inquired serial ports receives the response, the computer judges that the serial port is connected with one of the at least one measuring instrument and issues a verification command to the connected measuring instrument to perform a verifying process, wherein if the measuring instrument in the verifying process complies with the verification command, the computer addresses the measuring instrument.

10. The automatic control system according to claim 9, wherein the computer is equipped with or expansively connected with the plural serial ports.

11. The automatic control system according to claim 9, wherein the at least one measuring instrument and the corresponding serial ports are connected with each other through RS232 transmission interfaces.

12. The automatic control system according to claim 9, wherein if no response is received after the computer inquires a specified serial port of the plural serial ports according to one of the plural different communication protocols for a predetermined time period, the computer inquires the specified serial port according to another of the plural different communication protocols, wherein if no response is received after the specified serial port is inquired according to all of the plural different communication protocols, the computer judges that the specified serial port is connected with none of the at least one measuring instrument and inquires another serial port of the plural serial ports according to the plural different communication protocols.

13. The automatic control system according to claim 9, wherein after the measuring instrument connected with a specified serial port is addressed, the computer inquires other serial ports according to the plural communication protocols.

14. The automatic control system according to claim 9, wherein the computer comprises a memory unit, and the computer saves addressing results of the corresponding measuring instruments as an initiation file and stores the initiation file in the memory unit, wherein the initiation file is read by the computer when the automatic control system is operated in a next time.

15. The automatic control system according to claim 9, wherein the number of the plural serial ports is equal to or more than a number of the at least one measuring instrument, wherein each measuring instrument is connected with a corresponding serial port of the plural serial ports.

16. The automatic control system according to claim 9, wherein each of the plural communication protocols contains a Baud rate setting, a data bit setting, a stop bit setting and a parity bit setting.

17. The automatic control system according to claim 9, wherein the plural communication protocols are set and compiled according to applications of the at least one measuring instrument.

18. The automatic control system according to claim 9, wherein the verification command contains a predetermined brand data or a predetermined machine model data, wherein if a brand name or a model number of the connected measuring instrument is identical to the predetermined brand data or the predetermined machine model data, the computer judges that the connected measuring instrument complies with the verification command.
